(19) United States
(12) Patent Application Publication
(10) Pub. No.: US 2012/0097047 A1
(43) Pub. Date: Apr. 26, 2012

(54) Heat-Storage Cooker

(75) Inventors: Konrad Schönemann, Sulzfeld (DE); Michael Riffel, Oberderdingen (DE); Uwe Schaumann, Oberderdingen (DE); Wilfried Schilling, Kraichtal (DE); Norbert Gärtner, Ettlingen (DE)

(73) Assignee: E.G.O. Elektro-Gerätebau GmbH, Oberderdingen (DE)

(21) Appl. No.: 13/277,845

(22) Filed: Oct. 20, 2011

(30) Foreign Application Priority Data
Oct. 25, 2010 (DE) DE102010042877.9

(51) Int. Cl. A47J 36/00; H01L 35/30

(52) U.S. Cl. 99/339

(57) ABSTRACT

A heat-storage cooker has at least one heat source and a thermogenerator with a hot side and a cold side for generating electrical energy during operation of the heat source for the purpose of supplying the electrical energy to an electrical functional unit, in particular an electronic control means, of the heat-storage cooker. The hot side is provided close to the heat source with good thermal coupling to the said heat source, and the cold side is routed to the surrounding area, to a baking-oven muffle or to a cooking plate of the heat-storage cooker. Therefore, an electronic control means can be operated even in the case of a heat-storage cooker without an electrical connection.

### CROSS REFERENCE TO RELATED APPLICATIONS

This application claims the benefit of German patent application DE 10 2010 042 877.9, filed on Oct. 25, 2010, the contents of which are incorporated by reference for all that it teaches.

### FIELD OF APPLICATION

The invention relates to a heat-storage cooker having at least one heat source.

### BACKGROUND

It is known from DE 1 141 063 A that an electrically heated heat-storage cooker can have a plurality of cooking plates and a storage core together with a heating element as a heat source. In this case, the heating element is an electrical heating element; therefore, the heat-storage cooker necessarily requires an electrical connection.

Furthermore, attempts are being made to be able to use other functions in the case of gas-fired, oil-fired, or wood-fired heat-storage cookers. In particular, one aim is for an electronic control means to be able to program various operating modes.

### SUMMARY

The invention is based on the problem of providing a heat-storage cooker of the kind mentioned in the introductory part with which problems arising in the prior art can be avoided and further functions can be provided independently of an electrical connection, in particular with autonomous operation.

This problem is solved by a heat-storage cooker having the features as claimed herein. Advantageous and preferred refinements of the invention are the subject matter of the further claims and will be explained in greater detail below. The wording of the claims is included in the content of the description by express reference.

According to one embodiment of the invention, the heat-storage cooker has a thermogenerator with a hot side and a cold side. The thermogenerator generates electrical energy in a manner which is known per se during operation of the heat source for the purpose of supplying electrical energy to an electrical functional unit of the heat-storage cooker. To this end, the hot side is provided close to the heat source and has good thermal coupling to the said heat source. The cold side is routed to the surrounding area, to an oven or to a cooking plate of the heat-storage cooker for the purpose of carrying the thermal energy. In a further refinement, the cold side can equally be routed to the heat-storage means itself too, it being possible for this heat-storage means to be, for example, a water bath and for the temperature of the said heat-storage means to be lower than that of the heat source.

The thermogenerator is therefore heated by the heat source or thermal energy and is introduced at the hot side of the said thermogenerator. The thermal energy is drawn or dissipated at the cold side and the electrical energy is generated in a known manner from the said thermal energy.

It is possible to use the invention to obtain electrical energy even in heat-storage cookers with a non-electrical heating system or without an electrical connection. This electrical energy can be used to operate the above-mentioned convenience functions, for example an electrical controller that may comprise a microcontroller incorporating with all the known options. Furthermore, indicators or displays could be provided on the heat-storage cooker or, if the said heat-storage cooker has a baking-oven muffle, a fan for hot-air operation could be provided.

As discussed above, in one embodiment, the heat-storage cooker has an electronic controller comprising a microprocessor which has, in particular, a function memory, automatic programs and/or electronically actuated and evaluated operator control elements, particularly preferably in the form of touch switches. The energy requirement of the said electronic control means of a few watts can be generated by a thermogenerator which is not excessively large. The said electronic control means can carry out automatic sequential programs or so-called automatic programs particularly in a gas-operated heat-storage cooker which in that case also has, for example, at least one electronically controlled gas valve. Furthermore, a timer mode can also be provided, this mode indicating that a time period has elapsed at least by way of optical and/or acoustic indicators. Furthermore, the option of using touch switches itself is also highly advantageous.

In a further refinement of the invention, the heat-storage cooker can have an energy-storage means, advantageously in the form of a rechargeable battery or, under certain circumstances, comprising at least one capacitor. Therefore, electrical energy which has been generated by the thermogenerator, but that has not been directly consumed can be stored for later use. By way of example, the thermogenerator can also be permanently operated for as long as the heat source generates heat, and, for example, fill, and keep full, a relatively large energy-storage means even at a relatively low power. As a result, considerably more electrical energy than is being generated at a particular time by the thermogenerator can, in turn, be employed for actual use by the heat-storage cooker. As a result, and in conjunction with an abovementioned electronic control means, it may also be possible for the heat-storage cooker to heat up or pre-heat, as it were, automatically at specific programmed times, for example at midday and in the evening. At night, the said heat-storage cooker cools down again somewhat when the probability of it being used is very low.

In another embodiment of the invention, the heat-storage cooker can have a plurality of heat sources, for example, because it has a plurality of cooking plates or additionally has a baking oven with a muffle. In this case, the thermogenerator is advantageously coupled to that heat source which is designed for continuous or most-frequent or primary operation. This heat source is generally a heat source which is connected at least to a cooking plate since, even in the case of heat-storage cookers, cooking plates are used more frequently than any baking-oven muffles which may be present. Therefore, operation of the thermogenerator which lasts for as long as possible can be achieved.

In another embodiment of the invention, the heat-storage cooker can have heat sinks. In this case, the thermogenerator is coupled to that heat sink which remains cool, or less hot, even during permanent operation in such a way that a sufficiently large temperature difference is supplied to the thermogenerator for the purpose of operation of the said thermogenerator with the required power.

In a further embodiment of the invention, it is even possible for the heat-storage cooker not only to be not connected to an electrical energy source but to not have any such connection at all. In this case, it is always supplied with power in an autonomous manner.

Another embodiment involving a plurality of heat sources, the thermogenerator is coupled to can also depend on how easy it is to draw the thermal energy at the cold side of the thermogenerator and whether this is intended to be passed to the surrounding area, to a baking-oven muffle or to a cooking plate.

These and further features can be gathered not only from the claims but also from the description and the drawings, where the individual features can be realized in each case by themselves or in combination in the form of subcombinations in an embodiment of the invention and in other fields and can constitute advantageous and inherently patentable embodiments for which protection is claimed here. The subdivision of the application into individual sections and subheadings does not restrict the general validity of the statements made thereunder.

### BRIEF DESCRIPTION OF THE DRAWINGS

Exemplary embodiments of the invention are schematically illustrated in the drawings and will be explained in greater detail in the text which follows. In the drawings:

FIG. 1 shows a schematic functional illustration of a heat-storage cooker having a heat source, a cooking plate and a baking-oven muffle and also various mounting options for thermogenerators, and

FIG. 2 shows an alternative design of a heat-storage cooker having two cooking plates and two baking-oven muffles and also various mounting options for thermogenerators.

### DETAILED DESCRIPTION

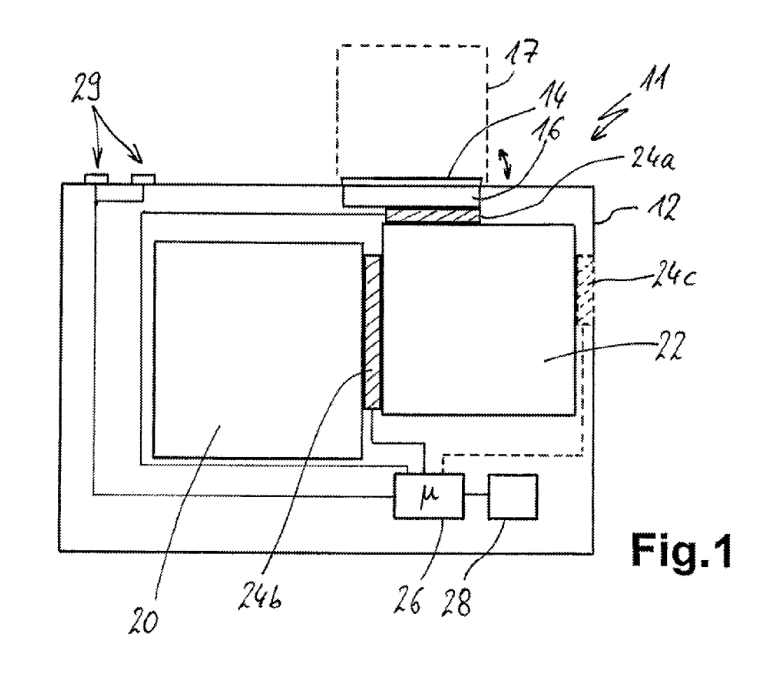

FIG. 1 illustrates a first embodiment of a heat-storage cooker 11 according to the invention. The heat-storage cooker 11 has a housing 12 and a cooking plate 14 on its upper face with a substructure 16. The cooking plate 14 can be covered by a cover 17 (illustrated in dashed lines), for example by means of a hinge, with the cover 17 providing a very high degree of thermal insulation, so that no heat or as little heat as possible is unnecessarily lost via the cooking plate 14 when the heat-storage cooker is not in use. Furthermore, the heat-storage cooker 11 has a baking-oven muffle 20 (only schematically illustrated).

The heat-storage cooker 11 has a heat source 22 of the conventional type; the manner and mode of heating of the said heat source does not play any fundamental role in the present invention. The heat source 22 is fundamentally arranged in a very highly thermally insulated manner outside or within the housing 12. The said heat source can contain a heat-storage means of the conventional type or has a heat-storage means of this type, the said heat-storage means, however, not being separately explicitly illustrated. The heat source 22 is thermally or thermally conductively connected to the substructure 16 and therefore to the cooking plate 14 by means of a first thermogenerator 24a, under certain circumstances by means of a heat-storage means. The heat source 22 is thermally conductively connected to the baking-oven muffle 20 by means of a second thermogenerator 24b.

In practice, either a direct coupling means or else possibly moving heat-transfer elements, in particular consisting of solid metal or in the form of heat pipes or the like, can be provided instead of the thermogenerators 24a and 24b. It is also possible to provide just one of the thermogenerators 24a or 24b. Furthermore, the said thermogenerators do not necessarily have to form the individual thermal or thermally conductive connection between the heat source 22 and the substructure 16 of the cooking plate 14 or the baking-oven muffle 20, but rather additional or structurally additionally special heat-transfer elements can be provided, as is customary per se.

Finally, a third thermogenerator 24c (illustrated in dashed lines) is also provided on the heat source 22, however this thermogenerator is fitted outside or on the housing 12 or a corresponding housing wall. Therefore, this means that it outputs the heat passing through it to the surrounding area.

All three thermogenerators 24a to 24c are connected to a controller 26 comprising a microprocessor in order to be supplied with energy. As mentioned in the introductory part, the thermogenerators 24a and 24b generate electrical energy by virtue of the temperature difference between the heat source 22 and, on the one hand, the substructure 16 together with the cooking plate 14 in the case of the thermogenerator 24a and, on the other hand, the baking-oven muffle 20 in the case of the thermogenerator 24b. During cooking processes, a temperature of approximately 100° C. to 250° C. usually prevails on the cooking plate 14, while the heat source 22 usually has a higher temperature of, for example, 300° C. to 400° C. in heat-storage cookers. In this case, a hot side of the thermogenerator is connected to the heat source 22 and a cold side is similarly connected to the substructure 16 or the baking-oven muffle 20. Since modern thermogenerators have a degree of efficiency of about 3% to 5% and, for example, 10 watts of electrical power are required in order to be able to operate the control means 26, a thermal power or heat of 200 watts to 330 watts has to be conducted through the thermogenerator. However, this is a realistic heating value both for a cooking plate 14 and for the baking-oven muffle 20 when it is considered that the said cooking plate and baking-oven muffle are continuously heated by the permanent heat transfer to the heat source 22 in any case and therefore are at the correct temperature. If more thermal power is conducted through a thermogenerator, it can generate yet more electrical energy and, for example, charge the energy—storage means 28 which is connected to the control means 26.

As an alternative, the thermogenerator can also be designed to be smaller or be designed for a lower continuous power using the energy-storage means 28. However, if this lower continuous power can be generated by the thermogenerator over a very long period of time, the energy-storage means 28 can be charged and additionally the control means 26 can be supplied with the necessary power overall from the said energy-storage means. In the case of relatively small thermogenerators of this kind, a further cited heat-transfer element is provided in addition to either the substructure 16 of the cooking plate 14 or the baking-oven muffle 20 in order to conduct enough heat from the heat source to the said substructure or baking-oven muffle.

The control means 26 is also connected to operator control elements 29 on the left of the upper face of the heat-storage cooker 11, it being possible to use the said operator control elements to control and/or monitor, for example, timer functions or else sequences relating to the manner of operation of the heat-storage cooker 11. These operator control elements 29 can be in the form of electronically actuated and evaluated touch switches and possibly also have an LCD or LED display (not illustrated) as a quasi-modern operator control device for the heat-storage cooker 11.

Both the baking-oven muffle 20, by way of a door, and the cooking plate 14, by virtue of its cover 17, can be very highly thermally insulated from the outside, so that the heat-storage cooker 11 therefore outputs as little heat as possible virtually in the inoperative state. This heat could firstly have an adverse effect on the surrounding area and secondly this is obviously bad for the energy balance or the energy consumption of the heat-storage cooker 11. However, if the heat-storage cooker 11 is additionally used as a room heater, this obviously does not have an adverse effect and is even planned. However, since this function is not required, and under certain circumstances would even be undesirable, at least at times of the year when it is hot, it should be possible to disable this effect and also the heat-storage cooker 11 should not consume an unnecessarily large amount of energy. For this reason, the thermal power from the heat source 22, through the thermogenerators 24a and 24b, to the substructure 16 of the cooking plate 14 or to the baking-oven muffle 20 is somewhat lower at inoperative times of the heat-storage cooker 11 since the said substructure of the cooking plate and baking-oven muffle also emit less heat. However, provision could still be made here for a thermogenerator 24 to generate some electrical energy, be it only a few watts. The energy-storage means 28 can continue to be charged with the said electrical energy over a relatively long charging period. Since the inoperative times of a cooker are usually several times longer than the operative times, the continuous power of a thermogenerator 24a or 24b in the inoperative state can be lower than the electrical power required by the control means 26 by a corresponding factor.

The thermogenerator 24c (illustrated in dashed lines) is provided as a third option for a thermogenerator, the said thermogenerator similarly bearing against the wall of the housing 20 and outputting heat there, this heat being conducted through the said thermogenerator from the heat source 22. In this case, the thermogenerator obviously bears against the housing 12 by way of its cold side, while it bears against the heat source 22 by way of its hot side. A thermogenerator 24c of this kind, which outputs the thermal energy conducted through it to the outside to the surrounding area, means a certain amount of energy is wasted because the heat is similarly output to the surrounding area, but if the heat-storage cooker 11 is also intended to be used as an abovementioned room heater, this heating power can be conducted straight through the thermogenerator 24c and output into the room. Since a considerably lower temperature usually prevails or more thermal energy is drawn at the cold side of the thermogenerator 24c than in the case of the thermogenerators 24a and 24b, the said thermogenerator 24c can also be smaller. An improved and therefore more efficient design can make provision for a cooling option which is customary per se, for example a separate cooling body, to be provided on the housing 12 in the region of the thermogenerator 24c.

Two of the three, or even all three, thermogenerators 24a, 24b and 24c can be provided in one heat-storage cooker 11 as an alternative or as desired. As a result, more thermal energy can, at least temporarily, flow through the thermogenerator than in the inoperative state of the heat-storage cooker 11 depending on the use of the heat-storage cooker 11, that is to say operation of the cooking plate 14 or else operation of the baking-oven muffle 20. Therefore, somewhat more electrical energy for the control means 26 and/or for charging the energy-storage means 28 can be generated at least by one of the thermogenerators.

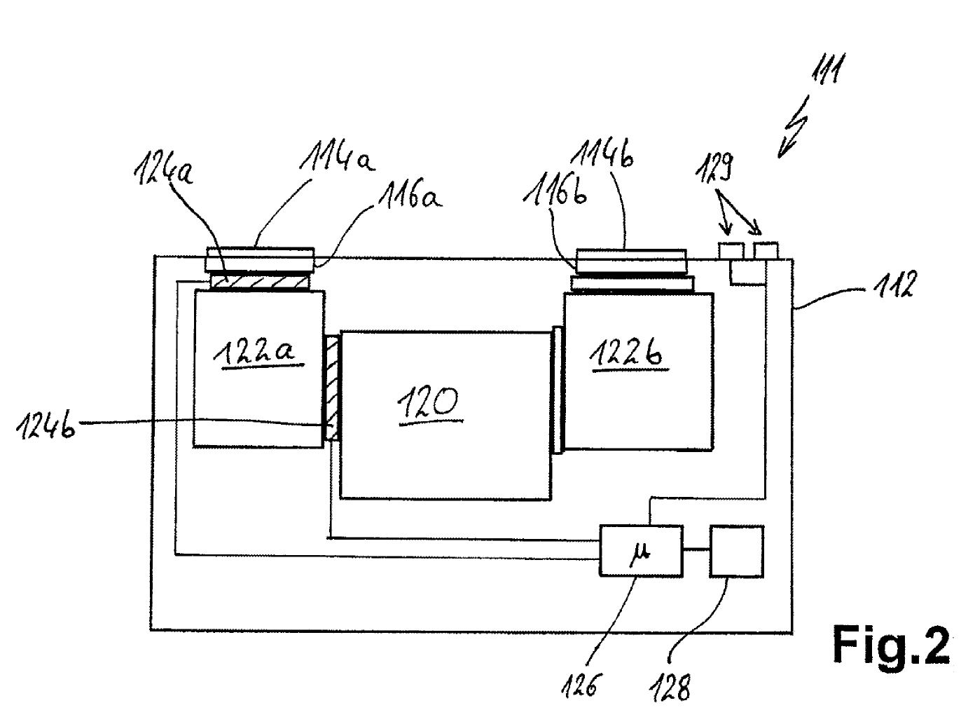

In the case of the alternative heat-storage cooker 111 according to the invention in FIG. 2, two cooking plates 114 with a substructure 116 on a housing 112 in each case are provided on the housing 112. A single baking-oven muffle 120 is provided. However, two heat sources 122 or heat-storage cores are provided in this case, specifically each directly beneath one of the cooking plates 114 and both adjoining the baking-oven muffle 120. However, thermogenerators 124a and 124b are provided only on the left-hand heat source 122a, specifically on a substructure 116a of the left-hand cooking plate 114a and on the left-hand region of the baking-oven muffle 120. The right-hand heat source 122b is not connected to or provided with thermogenerators at all and therefore cannot generate any electrical energy in the illustrated exemplary embodiment.

The thermogenerators 124a and 124b are connected to controller comprising a control means 126 such as a microprocessor which has an energy-storage means 128, as in FIG. 1. Furthermore, the said control means is connected to similar operator control elements 129 on the upper face of the heat-storage cooker 111.

In relation to the exemplary embodiment of FIG. 2, it should be explained that, in this embodiment of the heat-storage cooker 111, the left-hand cooking plate 114a, on account of its size or its arrangement, is that cooking plate which is used most frequently for cooking purposes. For this reason, the arrangement of the thermogenerator 124a in this location is just right. It is not necessary, yet advantageous, for the heat source 122a to also have the second thermogenerator 124b for the baking-oven muffle 120.

An embodiment of a heat-storage cooker in which a single heat source is connected to or heats a plurality of cooking plates is not illustrated but can be easily imagined and is often realized in practice. In that case, a thermogenerator can also be interposed for each cooking plate. As an alternative, a thermogenerator can be provided just for that cooking plate which, again on account of its size or arrangement, is provided for primary operation since the said thermogenerator is likewise operated most frequently. Therefore, the number of thermogenerators which are to be installed in the heat-storage cooker can be kept lower.

The size of the thermogenerators can be varied or correspondingly adjusted as a function of the temperature gradient of the heat source in relation to cooking plates, the baking-oven muffle or the surrounding area. When a plurality of thermogenerators are provided for a single control means, electrical energy can be generated either by all the thermogenerators at the same time or, as an alternative, primarily those thermogenerators through which a particularly large amount of heat is conducted or which are connected to a cooking plate or baking-oven muffle which is in operation can generate electrical energy. In that case, a lower temperature than is otherwise the case prevails on the cold side of the thermogenerator.

1. A heat-storage cooker comprising:
an electrical functional unit;
at least one heat source; and
a thermogenerator with a hot side and a cold side for generating electrical energy during operation of said heat source configured to supply electrical energy to said electrical functional unit, with said hot side being provided close to said heat source with good thermal coupling to said heat source, and with said cold side being routed to one of a surrounding area, a baking-oven muffle, a cooking plate, or a heat storage means of said heat-storage cooker.

2. The heat-storage cooker according to claim 1, further comprising an electronic controller comprising a microprocessor.

3. The heat-storage cooker according to claim 2, wherein said electronic controller is provided with a function memory.

4. The heat-storage cooker according to claim 2, wherein said electronic controller is provided with an automatic program.

5. The heat-storage cooker according to claim 2, wherein said electronic controller is provided with electronically actuated and evaluated operator control elements.

6. The heat-storage cooker according to claim 5, wherein said evaluated operator control elements are touch switches.

7. The heat-storage cooker according to claim 1, further comprising:
an energy-storage means for storing electrical energy generated by said thermogenerator.

8. The heat-storage cooker according to claim 7, wherein said energy-storage means comprises a rechargeable battery.

9. The heat-storage cooker according to claim 1, wherein a plurality of said heat sources is provided, with said thermogenerator being coupled to one of the plurality of heat sources that is designed for continuous or most-frequent or primary operation.

10. The heat-storage cooker according to claim 1, wherein a plurality of heat sinks is provided, with said thermogenerator being coupled to that heat sink which remains cool or less hot even during permanent operation in such a way that a sufficiently large temperature difference is supplied to said thermogenerator to generate electrical energy.

11. The heat-storage cooker according to claim 1, configured without an electrical connection to an external electrical energy source.

12. A heat-storage cooker comprising:
an electrical functional unit comprising a microprocessor for controlling the heat-storage cooker;
a plurality of operator control elements comprising touch switches configured to provide input to the microprocessor for operator control of the heat-storage cooker;
at least one heat source;
a thermogenerator with a hot side and a cold side for generating electrical energy during operation of said heat source configured to supply electrical energy to said electrical functional unit, with said hot side being provided close to said at least one heat source with good thermal coupling to said heat source, and with said cold side being routed to one of a surrounding area, a baking-oven muffle, a cooking plate, or a heat storage means of said heat-storage cooker; and
an energy storage device comprising a rechargeable battery storing electrical energy generated by said thermogenerator.
